(19) United States
(12) Patent Application Publication
(10) Pub. No.: US 2003/0012875 A1
(43) Pub. Date: Jan. 16, 2003

(54) CVD BST film composition and property control with thickness below 200 A for DRAM capacitor application with size at 0.1mum or below

(76) Inventors: Shreyas Kher, Campbell, CA (US); Yaxin Wang, Fremont, CA (US); Jun Zhao, Cupertino, CA (US)

Correspondence Address: APPLIED MATERIALS, INC., 2881 SCOTT BLVD. M/S 2061, SANTA CLARA, CA, 95050, US

(21) Appl. No.: 09/903,222

(22) Filed: Jul. 10, 2001

(51) Int. Cl. C23C 16/00

(52) U.S. Cl. 427/248.1; 427/255.28

(57) ABSTRACT

A multiple-step CVD process for producing thin metal-oxide films is disclosed. The process involves the use of the same and/or a different mixture of precursor gases and/or the same and/or different precursor flows for each step. The multiple-step process yields more precise control over film stoichiometry. Also disclosed is a film having superior film quality.

### BACKGROUND OF THE INVENTION

1. Field of the Invention

The invention relates to a process for the vaporization of liquid precursors and the deposition of a film with a thickness about 200 Å or less on a suitable substrate. Particularly contemplated is a process for the deposition of a metal-oxide film, such as a barium strontium titanium oxide (“BST”) film, on a silicon substrate to make integrated circuit capacitors that are useful in high capacity dynamic memory modules.

2. Discussion of the Background

The increasing density of integrated circuits (ICs) is driving the need for materials with high dielectric constants to be used in electrical devices, such as capacitors, for forming 256 Mbit and 1 Gbit dynamic random access memory devices (“DRAMs”). Capacitors containing high dielectric constant materials, such as perovskites, usually have much larger capacitance densities than standard SiO₂—Si₃N₄—SiO₂ stack capacitors, thereby making them the materials of choice in IC fabrication.

Because of its high capacitance, one perovskite of increasing interest as a material for use in ultra large scale integrated (“ULSI”) DRAMs is BST. Deposition techniques used in the past to deposit BST include radio frequency magnetron sputtering, laser ablation, sol-gel processing and chemical vapor deposition (“CVD”) using organometallic compounds.

A liquid source BST CVD process entails atomizing a compound, vaporizing the atomized compound, depositing the vaporized compound on a heated substrate and annealing the deposited film. This process requires control over the liquid precursors and gases from introduction from an ampule into a liquid delivery system through vaporization and, ultimately, to the surface of the substrate where it is deposited. The goal is to achieve a repeatable process that deposits a film of uniform thickness under the effects of a controlled temperature and pressure environment. To date, this goal has not been satisfactorily achieved. Known vaporizers lack temperature-controlled surfaces and the ability to maintain liquid precursors at a low temperature prior to injection into the vaporizer. This results in deposition of material in the injection lines of the vaporizer and premature condensation or unwanted decomposition of the precursors.

U.S. Pat. Nos. 6,082,714 and 6,077,562 disclose an apparatus and method that may be used to vaporize liquid precursors and deposit a metal oxide film such as BST on a substrate. The apparatus includes a body defining one or more fluid passages, a plurality of vaporizing surfaces disposed in the fluid passages, a heating member and a liquid injection member disposed in the inlet of the fluid passages to deliver one or more liquids into the plurality of vaporizing surfaces, the vaporizing surfaces forming a corrugated flow passage disposed laterally with respect to a centerline of the liquid injection member. The method involves delivering one or more liquid precursors to a vaporizer, vaporizing the one or more liquid precursors, delivering the vaporized precursors to a deposition chamber and depositing a film on a substrate.

Use of CVD to form a thin film on a substrate is one of the primary steps in the fabrication of modern semiconductor devices. Conventional thermal CVD processes supply reactive gases to the substrate surface where heat-induced chemical reactions can occur to produce the desired film. Plasma CVD processes promote the excitation and/or dissociation of the reactant gases by the application of radio frequency energy to the reaction zone proximate the substrate surface, thereby creating a plasma of highly reactive species.

As device sizes become smaller and integration density increases, improvements in processing technology are necessary to meet semiconductor manufacturers' process requirements. One parameter that is important in such processing is film deposition uniformity. To achieve a high film uniformity, among other things, it is necessary to accurately control the delivery of gases into the deposition chamber and across the substrate surface.

Moreover, with DRAM capacitor device feature sizes continuously shrinking, a much thinner dielectric film is required. Currently used dielectric film thicknesses of films such as BST have been greater than about 300 Å and, typically, up to about 500 Å. If the required film size is thinner than about 300 Å, especially below about 200 Å, it is critical to make film properties and composition uniform across the film thickness.

From the above, it can be seen that it is desirable to provide a method to accurately control the delivery of process gases to all points along the surface of the substrate to improve characteristics such as film uniformity. One method employed to improve film deposition uniformity is described in U.S. Pat. No. 6,070,551, which discloses a deposition chamber having at least a first set of nozzles for delivery of a first gas and a second set of nozzles for delivery of a second gas. Each set of nozzles is disposed centrally above the substrate to permit uniform dispersal of the gases. Despite this improvement, new techniques for accomplishing these and other related objectives are continuously being sought to keep pace with emerging technologies.

None of the references discussed above disclose a CVD process capable of depositing a BST film having a thickness of about 200 Å or less of sufficient uniform thickness and composition. A need for such a process, therefore, exists in the art.

### SUMMARY OF THE INVENTION

It is an object of the present invention to provide a method of depositing a thin metal-oxide film that includes a means for controlling film thickness even in films having a thickness of only a few angstroms.

Another object of the present invention is to provide a method that permits production of metal-oxide films having consistent stoichiometry regardless of film thickness.

Yet another object of the present invention is to provide a method that produces thin metal-oxide films that exhibit increased electrical performance.

According to the present invention, there is provided a multiple-step chemical deposition process wherein the same and/or a different mixture of precursor gases and the same and/or different precursor flows are used to deposit a thin metal-oxide film having a thickness of about 200 Å or less on a substrate. The process of the present invention provides greater and more precise control over film stoichiometry and, therefore, produces a thin metal-oxide film having consistent stoichiometry and increased electrical performance.

### BRIEF DESCRIPTION OF THE DRAWINGS

FIGS. 1A and 1B are diagrams showing an example of a CVD system that can be used to practice the method of the present invention.

FIG. 2 is a graph showing the effect of thickness on film composition when using the method of the present invention.

FIG. 3 is a graph showing the elimination of composition dependence on thickness as a result of use of the method of the present invention.

### DETAILED DESCRIPTION OF THE INVENTION

The present invention is directed to a multiple-step process of depositing a thin metal-oxide film. The process precisely controls the film composition of films having a thickness of about 200 Å or less. Film composition often depends on film thickness and oxygen flow. The present invention, therefore, is also directed to a multiple-step deposition process for obtaining stoichiometric films having a thickness of about 200 Å or less.

The present invention is directed to a deposition method that may be employed in liquid delivery CVD systems generally used to deposit thin metal-oxide films, as well as other films requiring vaporization of precursor liquids. The method of the present invention finds particular application in the fabrication of metal-oxide dielectrics useful in making capacitors that are used in ULSI DRAMs, as well as a number of other electrical devices. In general, devices that can be made in accordance with the present invention are those characterized by having one or more layers of insulating, dielectric or electrode material deposited on a substrate.

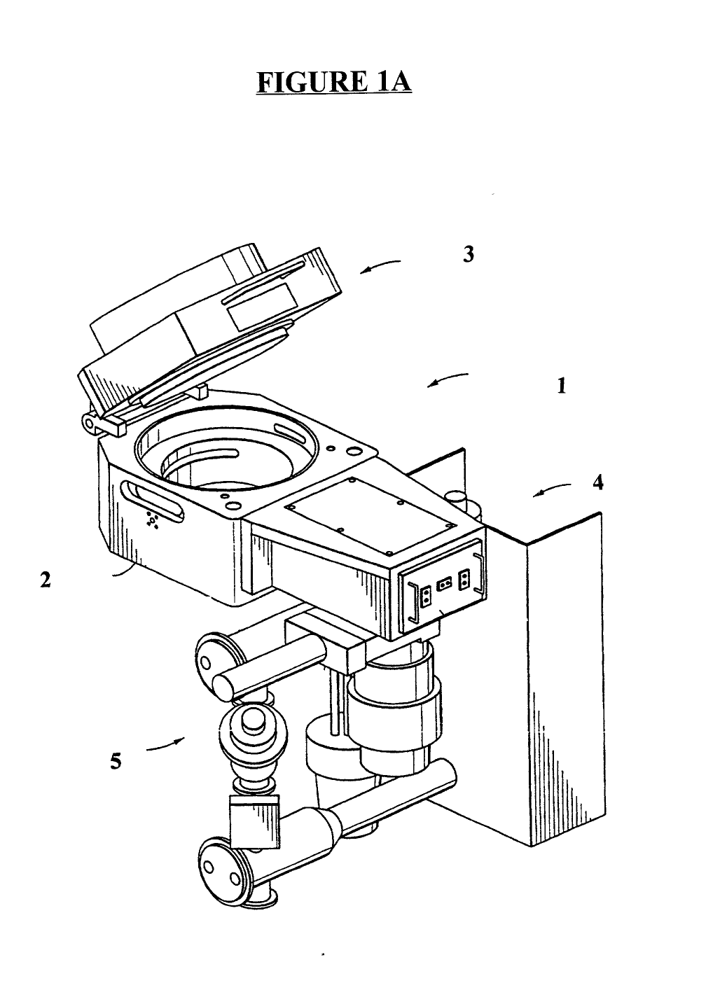

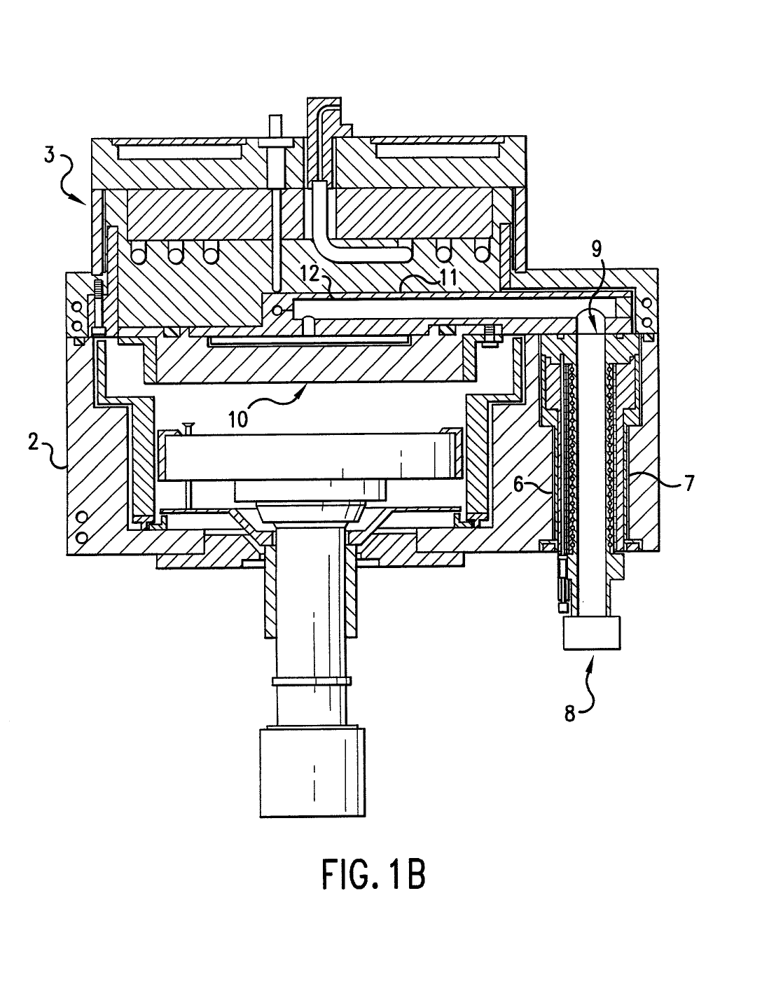

FIG. 1A and FIG. 1B are drawings of a typical CVD system 1 that may be used to practice the method of the present invention. U.S. Pat. No. 6,077,562 discloses such a system. As shown in FIGS. 1A and 1B, the system 1 generally includes a chamber body 2, a heated lid assembly 3, an integrated vaporizer module 4 and an exhaust/pumping system 5. Not shown in this figure, but a feature also to be employed in practicing the method of the present invention, is a liquid delivery system for supplying liquid precursors to the vaporizer module 4.

Referring now to FIG. 1B, the chamber body 2 defines one or more passages 6 for receiving a heated gas delivery feedthrough 7 having an inlet 8 and an outlet 9 to deliver one or more precursor gases into the gas distribution plate 10 mounted on the lid assembly 3. The gas outlet 9 is fluidically connected to a mixing gas manifold 11 that includes at least a first gas passage 12 to deliver one or more gases into the gas distribution plate 10.

Applicants have discovered that film uniformity can be enhanced if the film deposition is carried out in at least two steps using the same and/or a different mixture of precursor gases and the same and/or different precursor flows for each step. Accordingly, the present invention provides a method of depositing a uniform thin film having a thickness of about 200 Å or less. The method comprises delivering one or more liquid precursors to a vaporizer, vaporizing the one or more liquid precursors and delivering the vaporized precursors to a deposition chamber to deposit a film on a substrate. In the method of the present invention, the aforementioned sequence of steps are repeated at least one time. The contribution of the first sequence of steps to the total constitution of the film is about 50 Å or less. Each time the sequence of steps is carried out the mixture of precursor gases may be the same or different. Similarly, the flow rates of the precursor gases may be the same or different for each time the sequence of steps is carried out. Additionally, before repeating the aforementioned sequence of steps, there is, preferably, a waiting period. This waiting period may last for about 10 seconds to about 300 seconds.

The deposition method of the present invention is superior to prior art methods because this method is able to achieve film uniformity at film thicknesses of about 200 Å or less.

Exemplary metal-oxide layers that may be deposited using the method of the present invention include tantalum pentoxide (Ta₂O₅), a zirconate titanate (ZrₓTi_{y}Oⱼ, strontium titanate (SrTiO₃), barium strontium titanate (BST), lead zirconate titanate (PZT), lanthanum-doped PZT, bismuth titanate (Bi₄Ti₃O₁₂), barium titanate (BaTiO₃) or the like. Other materials that may be deposited include those materials having a narrow range between vaporization and decomposition.

The vapor that may be used in the deposition process of the present invention comprises first and second vaporized liquid precursors that may be used alone or may be combined in predetermined mass or molar proportions. For use in a deposition of BST, the first and second liquid precursors typically are organometallic precursors of the general class of β-diketones. Preferably, the first and second liquid precursors are β-diketonates of barium, strontium and titanium.

More preferably, the first liquid precursor (“BST-1”) is a mixture of barium and strontium polyamine compounds in a suitable solvent. For example, the first liquid precursor may be a mixture of bis(tetra methyl heptandionate) barium penta methyl diethylene triamine, commonly known as Ba(TMHD)₂, and bis(tetra methyl heptandionate) strontium penta methyl diethylene triamine, commonly known as Sr(THMD)₂. In the alternative, first liquid precursor may be a mixture of simply Ba(THMD)₂ and Sr(THMD)₂. Another alternative mixture for the first liquid precursor combines bis(tetra methyl heptandionate) barium tetraglyme, commonly known as Ba(THMD)₂ tetraglyme, and bis(tetra methyl heptandionate) strontium tetraglyme, commonly known as Sr(THMD)₂ tetraglyme. Suitable solvents include, for example, butyl acetate, tetrahydrofuran and the like. The second liquid precursor (“BST-2”) is preferably bis(tetra methyl heptandionate) bis isopropoxy titanium, commonly known as Ti(i-OPr)₂(THMD)₂, or other titanium metal organic sources, such as Ti(tBuO)₂(THMD)₂. Alternatively, the first precursor could be a mixture of Ba, Sr and Ti precursors of one proportion, and the second precursor could be a mixture of Ba, Sr and Ti precursors of another proportion.

The method of the present invention also has particular application with other liquid precursors that are volatile, as well as materials such as copper.

The BST process according to the present invention mixes the vaporized first and second liquid precursors with an oxidizing gas such as oxygen, N₂O, O₃ or combinations thereof, at a temperature above the vaporization temperature of the precursors and below a temperature that degrades the components. The flow velocity is independently controlled by the flow of auxiliary argon or other carrier gas input to the vaporizer. The process is sensitive to changes in temperature of the substrate, solvent content of the liquid precursors and concentration of the oxidizer in the combined gases. For example, increasing the substrate temperature increases the deposition rate; reducing the solvent content of the liquid precursors reduces the haze of the films; and controlling the oxidizer flow rate controls the roughness of the film and crystalline phase.

A preferred process according to the present invention deposits a BST film on a substrate mounted on a heated substrate holder using a gas distribution plate. The deposition occurs at less than about 7 Torr with a substrate temperature of less than about 500° C. Although gas flow rates are dependent upon the apparatus employed, a range of flow rates employed between about 10 mg/min and about 100 mg/min have been employed.

Substrates used in the present invention include primarily P-type and N-type silicon. Depending on the particular process chemistry and desired end product, other substrate materials may be used. Such suitable materials include other semiconductors such as, for example, germanium and diamond, compound semiconductors such as, for example, GaAs, InP, Si/Ge, SiC, and ceramics.

The selection of materials for the layers above the circuit element in an integrated circuit device depends on the device that is formed and other layers that a particular layer currently or subsequently contacts. For example, a DRAM requires a high permittivity capacitor, but the metal-oxide dielectric layer does not need to have ferroelectric properties.

Devices that can be made with the present system include, but are not limited to, 64 Mbit, 256 Mbit, 1 Gbit and 4 Gbit DRAMs.

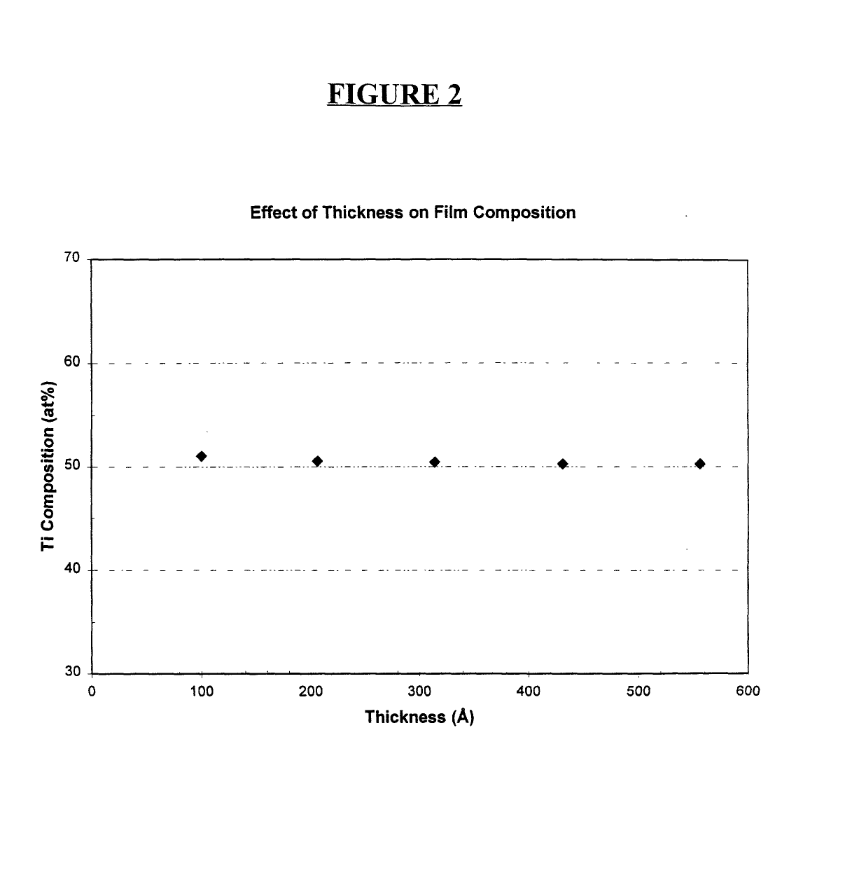

FIG. 2 is a graph showing the effect of the method of the invention on film composition. A two-step deposition process according to the present invention was employed to deposit a BST film. In the first step, the first liquid precursor was a mixture of Ba(TMHD)₂ and Sr(TMHD)₂ in tetrahydrofuran with a flow rate of about 56 mg/min, while the second liquid precursor was Ti(i-OPr)₂(TMHD)₂ with a flow rate of about 64 mg/min. The gas (O₂) flow rate was about 1000 sccm and was employed for about 35 seconds. Next, in the second step, the same precursors were used; however, they were used in different proportions. The first liquid precursor was used at a flow rate of about 40 mg/min, and the second liquid precursor was used at a flow rate of about 80 mg/min. The gas (O₂) flow rate was about 500 sccm and was employed for about 114 seconds. The results show that a consistent Ti composition (50%) was achieved for films between about 100 Å and about 600 Å.

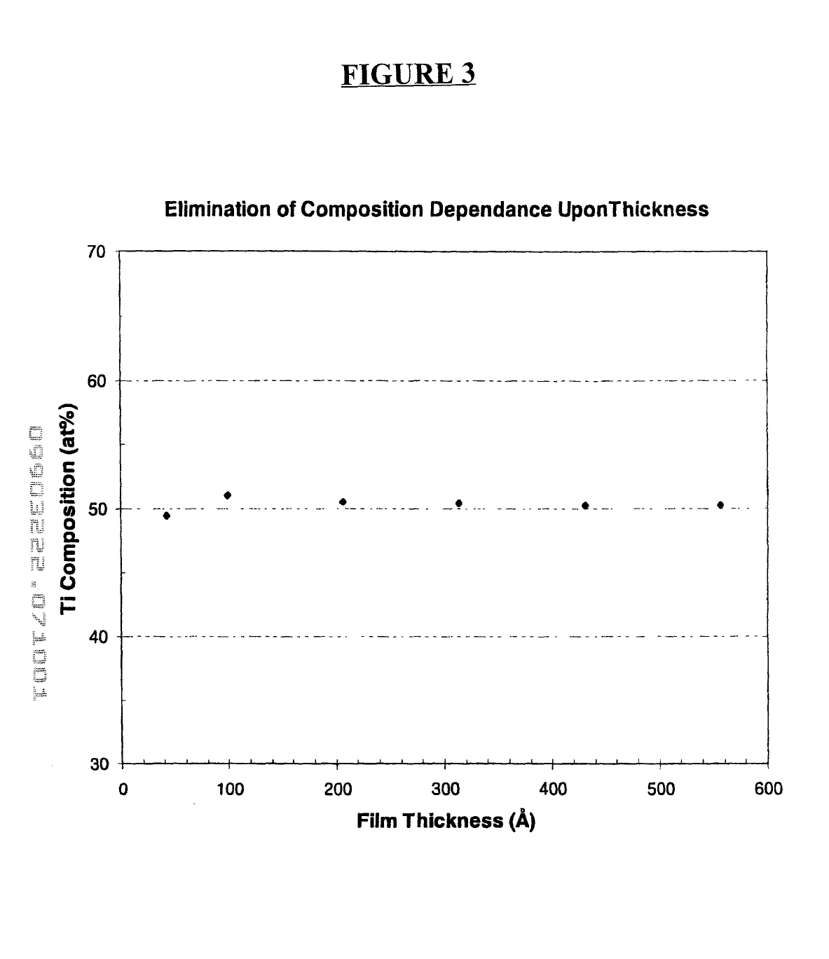

FIG. 3 is a graph showing the elimination of composition dependence on thickness as a result of using the method of the present invention. Again, a two-step deposition process according to the present invention was employed to deposit a layer of BST. In the first step, the first liquid precursor was a mixture of Ba(TMHD)₂ and Sr(TMHD)₂ in tetrahydrofuran. The flow rate of the first liquid precursor was about 56 mg/min. The second liquid precursor was Ti(i-OPr)₂(TMHD)₂ with a flow rate of about 64 mg/min. The gas (O₂) flow rate was about 1000 sccm. The same precursors were used in the second step but in different proportions. The first liquid precursor was used at a flow rate of about 40 mg/min, while the second liquid precursor was used at a flow rate of about 80 mg/min. The gas (O₂) flow rate was about 500 sccm. The results show that a consistent Ti composition (50%) was achieved for films having thicknesses between about 40 Å and about 600 Å.

These results show that the process of the present invention is capable of producing films having a thickness of about 200 Å or less of consistent stoichiometry and, therefore, is capable of producing thin metal-oxide films having increased electrical performance.

Having now fully described the invention, it will be apparent to one of ordinary skill in the art that changes and modifications can be made thereto without departing from the spirit or scope of the invention as set forth herein. Unless such changes and modifications depart from the scope of the invention, they should be construed as being included therein. It is intended, therefore, that the foregoing detailed description be understood from the following claims, including all equivalents, which are intended to define the scope of the invention.

What is claimed is:

1. A method of depositing a thin metal-oxide film having a uniform thickness of about 200 Å or less, comprising:
a) delivering one or more liquid precursors to a vaporizer;
b) vaporizing the one or more liquid precursors;
c) delivering the vaporized precursors to a deposition chamber to deposit a film on a substrate; and
d) repeating steps (a)-(c) at least one time.

2. The method of claim 1, wherein at least a first precursor flow rate is used in a first step and a second precursor flow rate is used in a second step.

3. The method of claim 2, wherein said first precursor flow rate and said second precursor flow rate are different from one another.

4. The method of claim 2, wherein said first precursor flow rate and said second precursor flow rate are the same.

5. The method of claim 1, wherein at least a first mixture of precursor gases is used in a first step and a second mixture of precursor gases is used in a second step.

6. The method of claim 5, wherein said first mixture of precursor gases and said second mixture of precursor gases are different from one another.

7. The method of claim 5, wherein said first mixture of precursor gases and said second mixture of precursor gases are the same.

8. The method of claim 5, wherein said first mixture of precursor gases and said second mixture of precursor gases comprises BST and oxygen.

9. The method of claim 1, wherein said process is halted for a predetermined waiting period prior to carrying out step (d).

10. The method of claim 9, wherein said predetermined waiting period is between about 10 seconds and about 300 seconds.

11. A film prepared by the method of claim 1.

12. A DRAM capacitor comprising the film of claim 11.
